(19) United States
(12) Patent Application Publication
(10) Pub. No.: US 2019/0088446 A1
(43) Pub. Date: Mar. 21, 2019

(54) MINIATURE ELECTRON BEAM LENS ARRAY USE AS COMMON PLATFORM EBEAM WAFER METROLOGY, IMAGING AND MATERIAL ANALYSIS SYSTEM

(71) Applicant: Weiwei Xu, Edgewood Plains (SG)

(72) Inventor: Weiwei Xu, Edgewood Plains (SG)

(21) Appl. No.: 16/154,350

(22) PCT Filed: May 5, 2017
(86) PCT No.: PCT/US2017/031391

§ 371 Date: Oct. 8, 2018

(51) Int. Cl. H01J 37/26; H01J 37/10; H01J 37/147; H01J 37/153; H01J 37/21

(52) U.S. Cl. CPC H01J 37/26; H01J 37/10; H01J 37/21; H01J 37/153; H01J 37/147

(57) ABSTRACT

An apparatus includes at least one electron beam column, with an electron emitter source, a gun lens focusing electrons from the electron emitter source into an electron beam, and a final beam forming aperture. Each electron beam column includes one or more of a double Wein filter disposed along a trajectory of the electron beam between the gun lens and the final beam forming aperture, and a dispersion corrector disposed along a trajectory of the electron beam after the final beam forming aperture.

### CROSS-REFERENCE TO RELATED APPLICATIONS

This application claims priority and benefit as a National Stage application under 35 U.S.C. 371 to international application serial no. PCT/US17/31391, filed on May 5, 2017, titled “MINIATURE ELECTRON BEAM LENS ARRAY USE AS COMMON PLATFORM EBEAM WAFER METROLOGY, IMAGING AND MATERIAL ANALYSIS SYSTEM”, which claims priority to U.S. application Ser. No. 62/332,588, filed on May 6, 2016, each of which is incorporated by reference herein in their entirety.

### BACKGROUND

Scanning electron microscopes (SEMs) are often used on wafer for metrology, imaging, material analysis of nanometer scale defects or pattern of interests. Different applications of ebeam metrology, imaging, and material analysis on wafer require different parameters. For example, applications may require different focused electron beam spot size, electron landing energies on wafer, numerical apertures, secondary electron signal extraction fields, and currents of focused electron beam on the wafer.

To achieve the best performance at different sets of parameters, the hardware of electron optical columns need to be designed differently. For example, EDX analysis using 5 kV landing energy will not be able to excite and observe Fe Kα and Fe Kβ X-rays, which are in an energy status between 6 kV and 8 kV. Electron beams with 10 kV landing energy beam would be able to excite and observe Fe Kα and Fe Kβ X-ray.

Another example is that when critical dimension measurement scanning electron microscope (CDSEM), measures line width roughness (LWR) on an after-development layer of photoresist, it requires low landing energies around 300 eV in order to avoid shrinking of the photoresists. One more example is that physical defect inspection SEM and defect review SEM may need electron beam conditions with a small semi-angle of the focused beam at the wafer to achieve large depth of focus so that defects of 3D transistors can be imaged clearly.

A typical electron beam column may include, but not limited to, electron source, gun lens, beam defining aperture, condenser lenses, final beam current limit aperture, alignment deflectors, scanning deflectors, electron detectors, signal amplifiers, and objective lenses. An electron beam column usually includes the complete mechanical structures necessary to obtain a scanning electron beam image. Each electron beam column hardware design may need different or additional features to achieve optimized performance for different applications. As a result, there are different columns designed to suit best application purposes in different applications on a wafer.

Most importantly, different objective lens designs are needed for different applications. Conventional ebeam imaging lenses are excited by electrical currents, which is bulk (typically larger than 200 mm in diameter) and not able to be miniaturized for a high density column array for a 300 mm wafer. When different columns with coil current excited lens for different applications are integrated into a single vacuum chamber, the vacuum chamber and wafer stage will be too bulky and expensive.

Electron beam imaging columns using an objective lens that uses permanent magnets can be built to a very small volume without interference with each other. Differentiating the electron optical designs of the permanent magnet lenses and other electron optical components in each column will allow different columns to achieve optimized performance in different applications, for example CDSEM, Review SEM, Physical Defect Inspection SEM, Electrical Defect Inspection SEM, EDX material identification analyzer, and thin film measurement using ebeam induced X-ray.

All electron sources have energy spreads, which causes chromatic aberration of the final focused electron probe on the sample. Chromatic aberration prevents a lens to focus all electrons with different energy to the same convergence point, causing a degraded resolution. A single Wien Filter and an energy filtering aperture can be used to reduce the energy spread but it also shifts virtual sources of electrons with different energies. As a result, this causes shifts of focusing positions of electron on the focal plane according to their energies. Additional dispersion compensation must be used to bring virtual sources of electrons with different energies back to the same position so that there are no shifts of electron-focusing positions according to their energies.

There are also other sources of dispersion in a scanning electron beam system. For example, when an electron beam scans through a magnetic focusing lens in a large angle with respect to the optical axis, there is a relatively large component of the lens axial field, which is perpendicular to the traveling direction of the electrons. This perpendicular field causes dispersion of electrons according to their energies. Both magnetic electron-beam-focusing lenses and electrostatic electron-beam-focusing lenses suffer from this dispersion just like in electrostatic or magnetic spectrometers, although the dispersion direction is different respectively. This causes the shifting of electron focusing position according to their energies, and a chromatic electron beam with energy spread distribution will be focused to a line profile on the focal plane instead of a point.

These dispersions are determined by the direction and distance away from the electron optical axis of scanned electron beams on the sample. Because the electron beam scans in both X and Y directions to form a 2D image, dispersion is also present in both X and Y directions. For another example, when a Wien Filters is used in the primary electron beam path, primary electron energy dependent focusing shifts are also present due to the dispersion of the beam separating Wien Filter. In order to optimize the resolution of the scanning electron beam system, these 2D dispersions from different causes must be compensated in both X and Y direction.

Traditional omega energy filter is able to introduce a dispersion while bring the primary electron beam trajectory back to electron optical axis after the primary electron beam leave the omega filter. However, a single omega filter only has dispersion in one planar axis, thus limiting its applications on 2D dispersion corrections. 2 omega filters are able to correct 2D dispersion, but they are expensive and complicated to manufacture. Another possible solution is using 2D Wien Filters to introduce the dispersion in 2 axis while keep the primary electron beam trajectory on the electron optical axis. However, 2D Wien Filters need to match the overlapped magnetic and electrical field distributions, thus very difficult to optimize the design and to manufacture.

### BRIEF SUMMARY

Miniature permanent magnet electron lenses, which may include a permanent magnet lens with a low magnetic leakage field and a coil driven adjustment lens to substantially eliminate the leakage field, are used to create small array of electron beam column for metrology, imaging, and material analysis purposes. The array includes at least one electron beam column.

Multiple columns, which are designed for different applications, are provided in a single system to enable users to choose which column hardware is most suitable for the targeted application at a time. The multiple columns are integrated in a single system, sharing many common components, including but not limited to vacuum chamber, vacuum pumps, wafer stages, scanning signal generators, high voltage biasing power supplies, detector signal digitizers, and main controlling software.

Logic of the system can choose the most suitable electron optical imaging column for different electron beam applications. Each column, including the permanent magnet lens unit and other column components, has its own rotational symmetry, and carefully excludes any common source for magnetic excitation or common magnetic conducting material, which will create symmetry mismatch. This provides excellent local symmetry when the lens and column units are assembled in a 2D array.

Each lens may have its own source. In this case, there will only be one electron beam and electron column in use for imaging purposes, while other beams are turned off by high voltage electron beam blanker. This eliminates cross signal interactions between different columns, and eliminates unnecessary electron beam induced contamination or damage on the wafer.

All columns may each use an independent source for the best performance of that column. In order to say cost, all columns also may share a single source, and the column which is most suitable for the application will be moved under the single source to align the optical axis of the source and the optical axis of the column to acquire an image. All columns may share a single set of electrical components. For example, all columns may share the same scanning signal, detector amplifier, high voltage controls, and digitizer.

A main magnetic field in the air is below the lens bottom, so that when lens arrays are assembled together, there is little interference between neighboring lens units. There is no shared or joint functional part between different lens and column unit, so that the lens and column units can be arranged at different distance for different applications. Lens units may be assembled at equal or unequal varying distances between each of the lenses.

Every lens unit has its own axial symmetric side shielding magnetic conductor, which effectively prevents leakage magnetic field in the optical axis between electron source and main objective lens. This allows for optimal image performance.

Each column may have different or additional components compared to other columns. Each column may have different electron source design parameters compared to other columns.

Each column may have a double Wien filter system to reduce the primary electron beam energy spread.

Each column may include a dispersion correction system using two 2D electrostatic deflectors and one 2D magnetic deflector. The electrostatic deflectors may be electrostatic quadrupoles, octupole, or duodecatupoles. In this dispersion correction system, all deflectors are not used for sample area scanning, but only to correct dispersion errors. The excitations of the deflectors can be synchronized with scanning signals so that dispersion errors can be corrected across the whole scanned area.

Each column may include a dispersion correction system using two 2D magnetic deflectors and one 2D magnetic deflector. The electrostatic deflectors may be electrostatic quadrupoles, octupole, or duodecapoles. In this dispersion correction system, all deflectors are not used for sample area scanning, but only to correct dispersion errors. The excitations of the deflectors can be synchronized with scanning signals so that dispersion errors can be corrected across the whole scanned area.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates four electron beam columns in an array 100 for different applications in accordance with one embodiment.

FIG. 2 illustrates objective lens unit 200 an objective lens unit with permanent magnet lens and adjustment lens in accordance with one embodiment.

FIG. 3 illustrates an electron beam column 300 with no pre-sample beam cross over to reduce electron-electron column interaction in accordance with one embodiment.

FIG. 4 illustrates an electron beam column 400 with pre sample beam cross over to control semi angle of focused beam on the wafer in accordance with one embodiment.

FIG. 5 illustrates a system 500 comprising an electrical beam blanker to select a column for an application in accordance with one embodiment.

FIG. 6 further illustrates the system 500 comprising an electrical beam blanker to select a column for an application in accordance with one embodiment.

FIG. 7 illustrates a single Wein filter 700 dispersion causes the virtual source shift of primary electrons with different energies.

FIG. 8 illustrates an exemplary profile of beam focused on the sample 800, in which a single Wien filter will cause focused position shifts of primary electrons with different energies on the focusing plane.

FIG. 9 illustrates a double double Wein filter 900 combination will correct the primary electron energy related focused position shifts of the first Wien filter on the focusing plane.

FIG. 10 illustrates that magnetic lens fields will have components perpendicular to the electron beam path, causing dispersion in large field of view.

FIG. 11 illustrates that there is focused position shifts of primary electrons 1100 with different energies at a distance away from the electron optical axis, while there is no such primary electron energy related shifts on the electron optical axis.

FIG. 12 illustrates a dispersion corrector 1200 of two 2D electrostatic deflectors and one 2D magnetic deflector to correct electron beam dispersion on the sample plane, which may be caused by Wien Filters or an objective lens field in large field of view scanning mode. The electron beam is finally deflected back to the original direction and position of primary electron optical axis.

FIG. 13 illustrates another dispersion corrector 1300 in accordance with one embodiment.

FIG. 14 illustrates that when the dispersion correction using configurations of deflectors in FIG. 12 and FIG. 13 are synchronized with scanning signals, the dispersion errors can be fully corrected (corrected dispersion effects 1400) across the whole scanned field of view.

FIG. 15 illustrates an electron beam column 1500 including the double Wein filter monochromator (double Wein filter 900, dispersion corrector 1200) and a dispersion error corrector using two 2D electrostatic deflectors 1202 and one 2D magnetic deflector 1206.

FIG. 16 illustrates an electron beam column 1600 including a double Wein filter (double Wein filter 900, dispersion corrector 1300) monochromator and a dispersion error corrector using two 2D magnetic deflectors 1302 and one 2D electrostatic deflector 1304.

FIG. 17 is an example block diagram of a computing device 1700 that may incorporate embodiments of the present invention.

### DETAILED DESCRIPTION

Disclosed herein is a single unit of electron beam system with at least one electron beam columns, which are used for imaging, measuring, and material analysis purposes. The system utilizes different electron optical column designs to achieve best performance in a given application. The electron beam columns share other components, including, but not limited to, the same vacuum chamber, voltage control, scan signals, digitizers, and wafer stage.

Some column design may have no electron beam focus cross-over before the sample to minimize electron-electron interactions. Some column design may have electron beam focus cross-over before the sample to precisely control the semi-angle of the focused beam at the sample at different conditions of landing energies and beam currents.

When independent sources are used for each column, the raw beam current for each column can be different so that high resolution and low beam current applications can be carried out in columns with low raw beam current from the source to reduce electron to electron interaction of the focused electron beam.

Each column can be switched on and off by using the electrical beam blanker. System users can choose the best electron beam column for the targeted application. Only one column is used for imaging, metrology, or material analysis purposes at a point of time, while other columns are not in use by blanking the electron beam using the electrical beam blanker.

The same system components, for example scanning signal generation and imaging computer, may be used for different electron beam, metrology, imaging and material analysis applications. Some columns may use different electronics and additional components to achieve the best performance in the targeted application. For example, critical dimension SEM may require electronics to be more repeatable and with minimum thermal related drift. Some column may have additional components for material analysis, for example, EDX and EWX analysis. Some columns in the array may incorporate a monochromator with double Wien filter electron energy in order to reduce the primary electron energy spread. Some columns in the array may add a dispersion correction system using a series of magnetic and electrostatic deflectors to correct dispersions in the system. Some columns in the array may be designed to be the same so that when one of the columns fails due to column hardware malfunction, another backup column can be used.

Different applications of the system include but are not limited to critical dimension SEM, defect review SEM, physical defect inspection SEM, electrical defect inspection SEM, and thin film thickness measurement.

A single electron beam imaging and material analysis system with multiple columns, which are optimized for different applications, enables different applications with hardware column designs offering best performance of that particular application. A single imaging system can be used for multiple imaging or material analysis purposes. Higher efficiency is achieved because wafers do not need to be transferred from one electron beam imaging system to another system to take images of different applications. A common electron beam imaging and material analysis platform saves manufacturing and management costs due to economies of scale.

The throughput of different applications of the wafer fab can be dynamically adjusted by adjusting the use time of different imaging and material analysis columns in a single system. Without a common platform and multiple-application electron beam imaging system, more throughput for a particular application can only be achieved by purchasing an electron beam imaging systems designed for that particular application.

High electron beam optical performance can be achieved in each of the different columns using strong objective lenses, which comprises permanent magnets. Using small and compact permanent magnet lenses, a small foot print of electron beam imaging and material analysis is achieved. This saves cost and design complexity of the vacuum chamber and wafer stage.

A primary electron energy filtering system, which also corrects the virtual source shifting using two Wien Filters, is disclosed. A first Wien Filter may be used above the final beam forming aperture in order to reduce the energy spread, while another Wien filter can be used in between the first Wien Filter and the beam forming aperture in order to compensating the virtual source shifting caused by the first Wien Filter. This two Wien Filter system generate an angular dispersion for different primary electron energies while keep virtual source at the same point for primary electrons with different energies.

A 2D dispersion correction system using a combination of non-overlapping magnetic and electrostatic deflectors is disclosed. In one illustrative embodiment, two 2D electrostatic deflectors and one 2D magnetic deflector are used to create the dispersion compensation. The first 2D electrostatic deflector is placed furthest from the sample and deflects the primary electron beam away from the electron optical axis. The 2D magnetic deflector is placed below the first electrostatic 2D deflector and deflects the primary electron beam back towards the electron optical axis. A second 2D electrostatic deflector is placed below the magnetic deflector and corrects the direction of the primary electron beam when it comes back to the electron optical axis so that the electron travels along the same path of electron optical axis of the primary electron beam, but a dispersion correction is introduced. Because the dispersion of electrostatic deflectors is stronger than magnetic deflectors, there is a dispersion introduced when the electron travels in the same direction and same optical axis. In these configurations, 2D dispersion control both in directions and magnitude can be achieved with correct excitation ratios of the electrostatic and magnetic deflectors while the electron beam exits on its original optical axis. There may be no overlapping of magnetic and electrostatic deflectors, therefore it is much simpler to manufacture.

In another illustrative embodiment, two 2D magnetic deflectors and one 2D electrostatic deflector are used to create the dispersion compensation. The first 2D magnetic deflector is placed furthest from the sample and deflects the primary electron beam away from the electron optical axis. The 2D electrostatic deflector is placed below the first electrostatic 2D deflector and deflects the primary electron beam back towards the electron optical axis. A second 2D magnetic deflector is placed below the magnetic deflector and corrects the direction of the primary electron beam when it comes back to the electron optical axis so that the electron travels along the same path of electron optical axis of the primary electron beam, but a dispersion correction is introduced. Because the dispersion of electrostatic deflectors is stronger than magnetic deflectors, there is a dispersion introduced when the electron travels in the same direction and same optical axis. In these configurations, 2D dispersion control both in directions and magnitude can be achieved with correct excitation ratios of the electrostatic and magnetic deflectors while the electron beam exits on its original optical axis. There may be no overlapping of magnetic and electrostatic deflectors, therefore it is much simpler to manufacture.

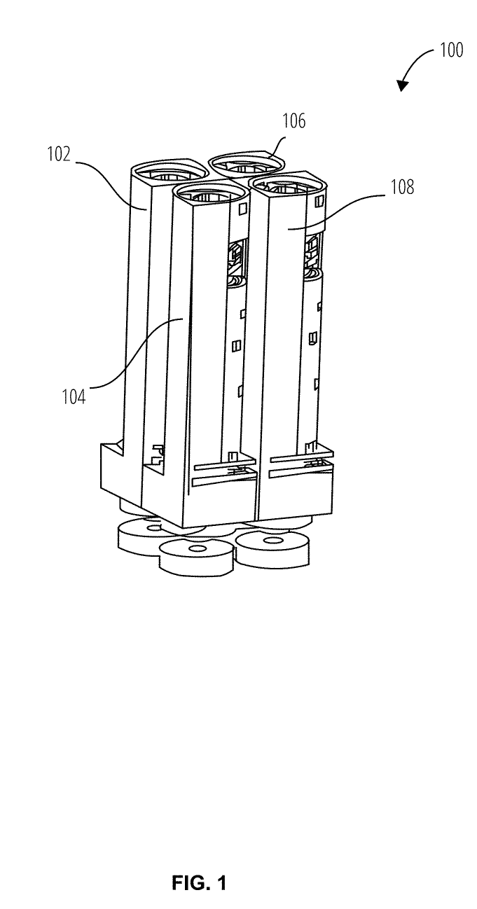

FIG. 1 illustrates four electron beam columns in an array 100 for different applications in accordance with one embodiment. The array 100 in this example comprises an EDX column 102, an electrical defect inspection column 104, a CDSEM column 106, and a physical defect inspection column 108.

The array 100 thus comprises multiple electron beam focusing columns in an integrated system with shared vacuum, electrical, and mechanical components to provide a multiple functional common platform. Ring shape permanent magnets may be used to generate strong magnetic fields for the final-stage high performance objective lens. Using permanent magnet lenses enables compact sized multi-column hardware to be integrated into a common vacuum chamber. Each column in the array can operate independently from the others, and can be designed and manufactured to optimize for particular applications including metrology, imaging, and material analysis.

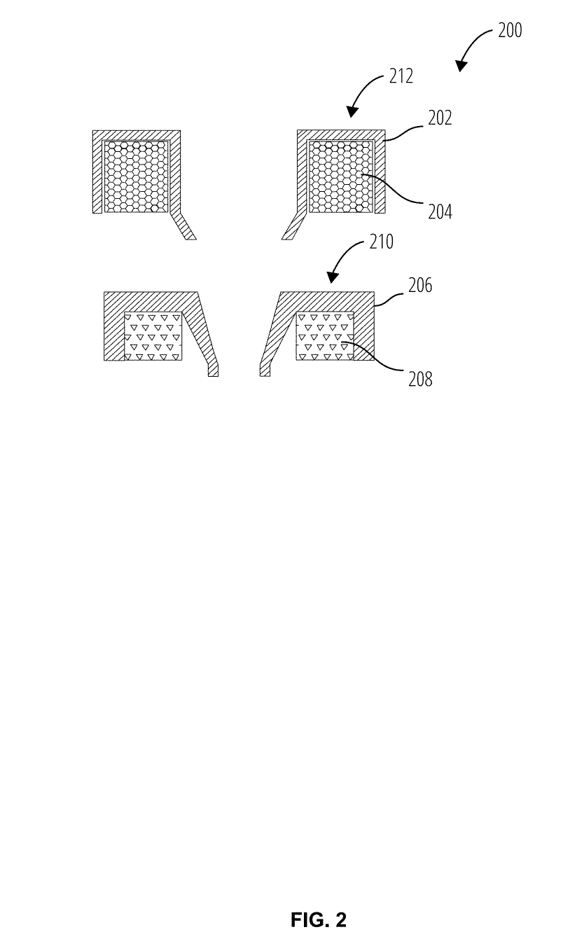

FIG. 2 illustrates objective lens unit 200 an objective lens unit with permanent magnet lens and adjustment lens in accordance with one embodiment. The objective lens unit 200 comprises an adjustment lens magnetic conductor 202, an adjustment lens coil 204, a main focus lens magnetic conductor 206, and a permanent ring magnet 208. In this example, each element is circular and is illustrated in a cutaway cross-sectional view.

A strong permanent magnet lens 210 and a weaker adjustment lens 212 driven by a coil may be used in the column to achieve high electron beam performance without leakage magnetic field in a compact physical size.

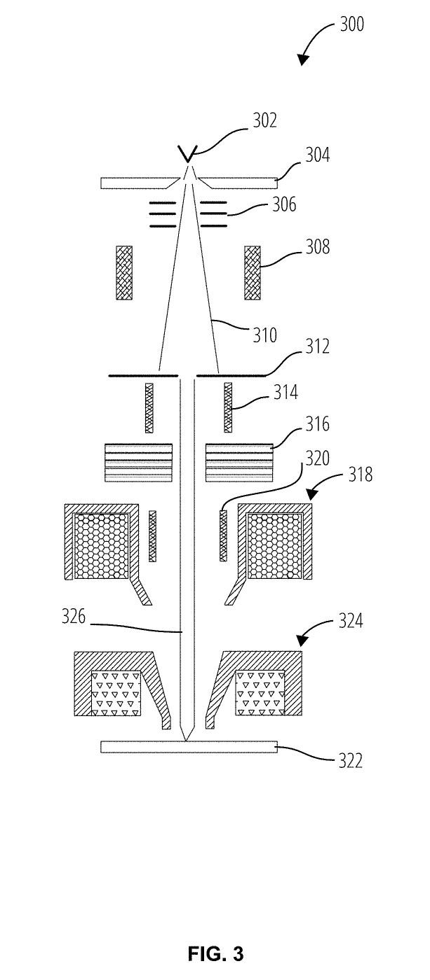

FIG. 3 illustrates an electron beam column 300 with no pre-sample electron beam 326 cross over to reduce electron-electron column interaction in accordance with one embodiment. The electron beam column 300 comprises an electron source 302, a beam defining aperture 304, a gun lens 306, a beam blanker 308, an electron beam 310, a beam current limiting aperture 312, an upper scanning deflector 314, an electron detector 316, a coil driven adjustment lens 318, a lower scanning deflector 320, a permanent magnet driven objective lens 324 and a wafer 322.

The operation of the electron beam column 300 will be readily apparent to those of ordinary skill the art.

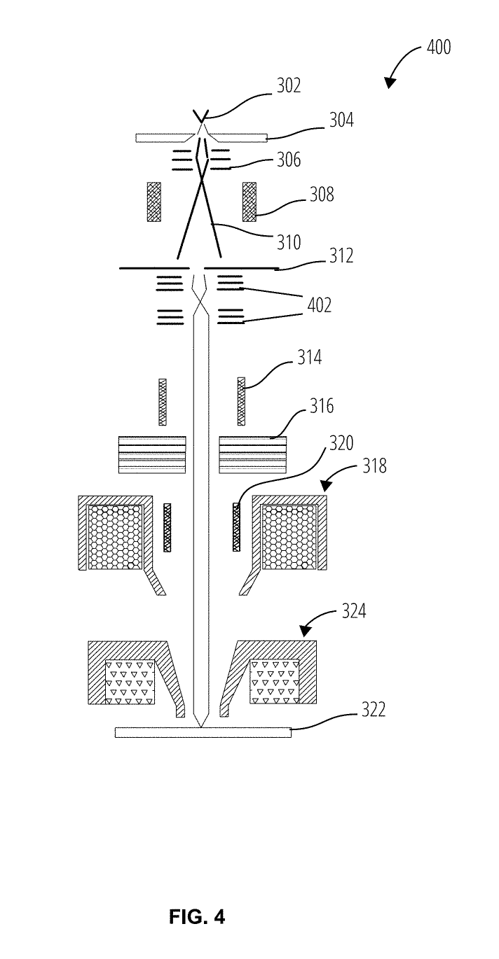

FIG. 4 illustrates an electron beam column 400 in which pre sample beam cross-over is used to control the final beam and diameter of the beam profile before entering the final objective lens.

Operation of the electron beam column 400 as influenced by the condenser lenses 402 will be readily understood to those of ordinary skill in the art.

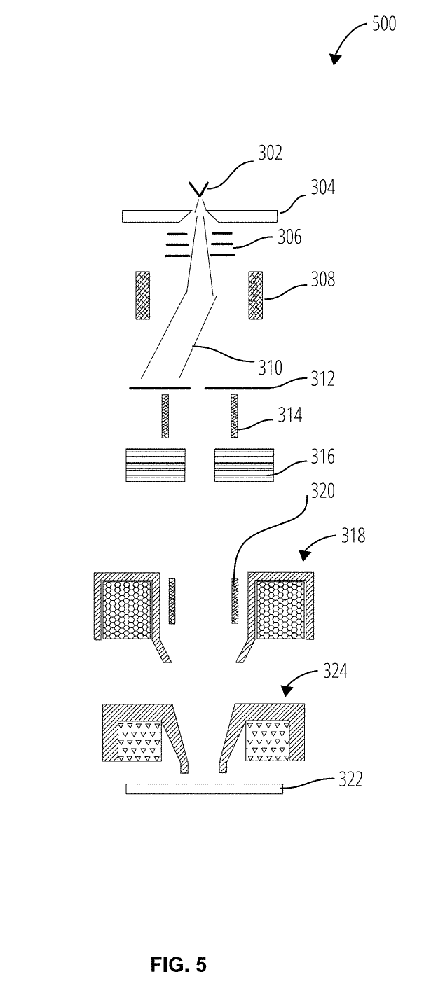

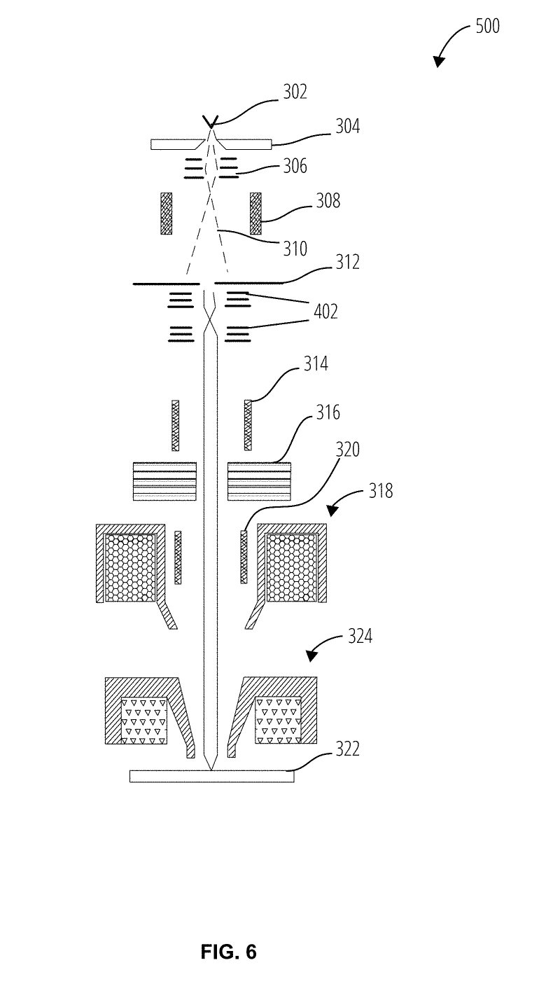

FIG. 5 and FIG. 6 illustrate a system 500 comprising an electrical beam blanker to select a column for an application in accordance with one embodiment. The beam blanker 308 is operated to select one of the columns for the application, while the other column has no beam current passing through the final beam current limiting aperture. In FIG. 5 the beam blanker 308 is turned ON to block the electron beam 310 from passing through the beam current limiting aperture 312. In FIG. 6 the beam blanker 308 is turned OFF to enable the electron beam 310 to pass through the beam current limiting aperture 312.

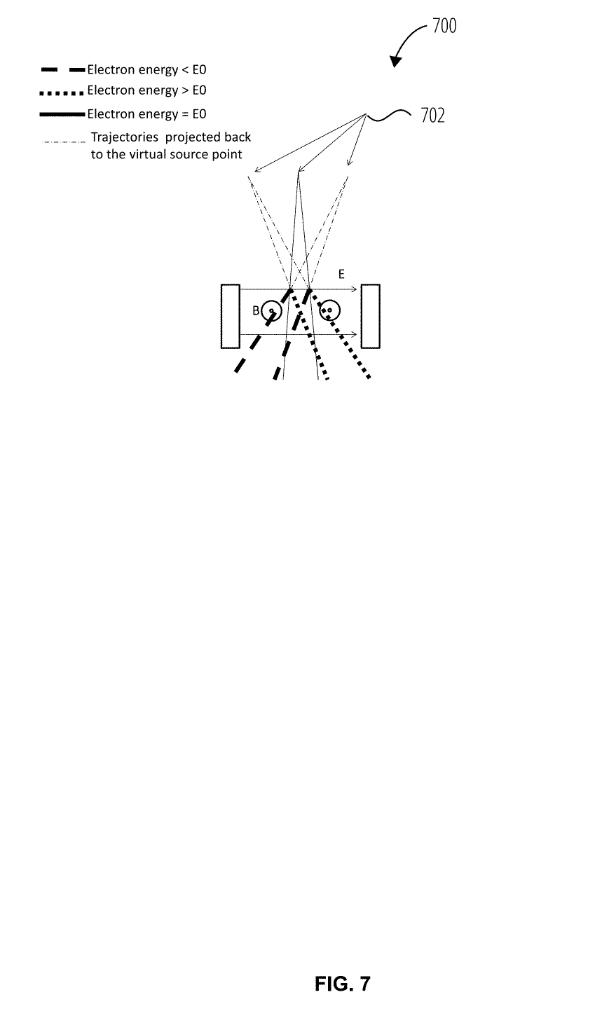

FIG. 7 illustrates a single Wein filter 700 dispersion causes the virtual source shift of primary electrons (electron virtual source points 702) with different energies.

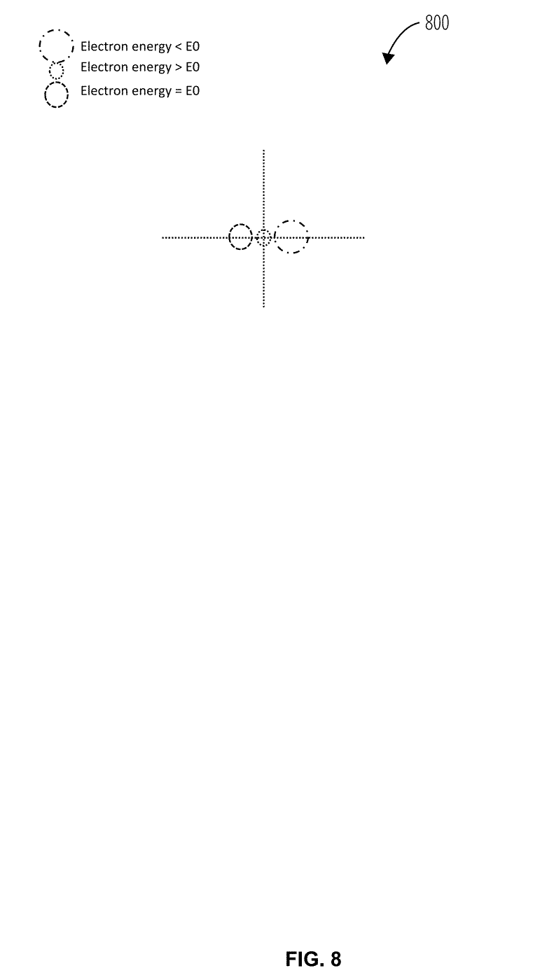

FIG. 8 illustrates an exemplary profile of beam focused on the sample 800, in which a single Wien filter will cause focused position shifts of primary electrons with different energies on the focusing plane. When a single Wien filter is used, electrons with different energy will be focused at different position on the sample due to the shifting of virtual source positions.

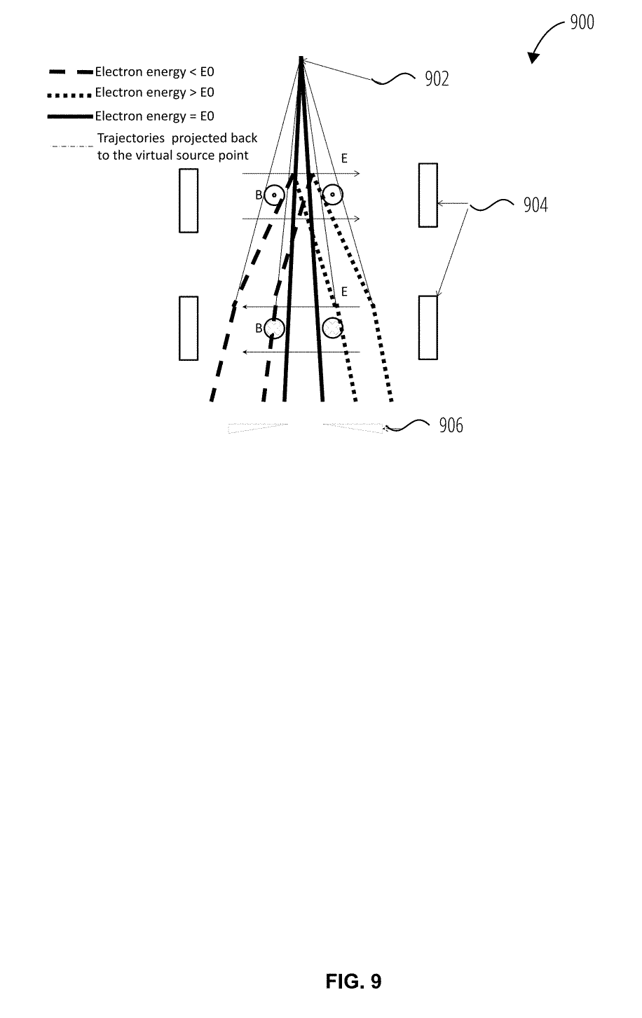

Referring to FIG. 9, in a double double Wein filter 900 combination, electrons emanate from an electron virtual source point 902, and through an electrostatic deflector 904 to a final beam-forming aperture 906.

FIG. 9 illustrates a double double Wein filter 900 combination will correct the primary electron energy related focused position shifts of the first Wien filter on the focusing plane. A double double Wein filter 900 before the final beam-forming-aperture setup will provide energy filtering while keeping virtual sources of electrons with different energies at the same virtual source point.

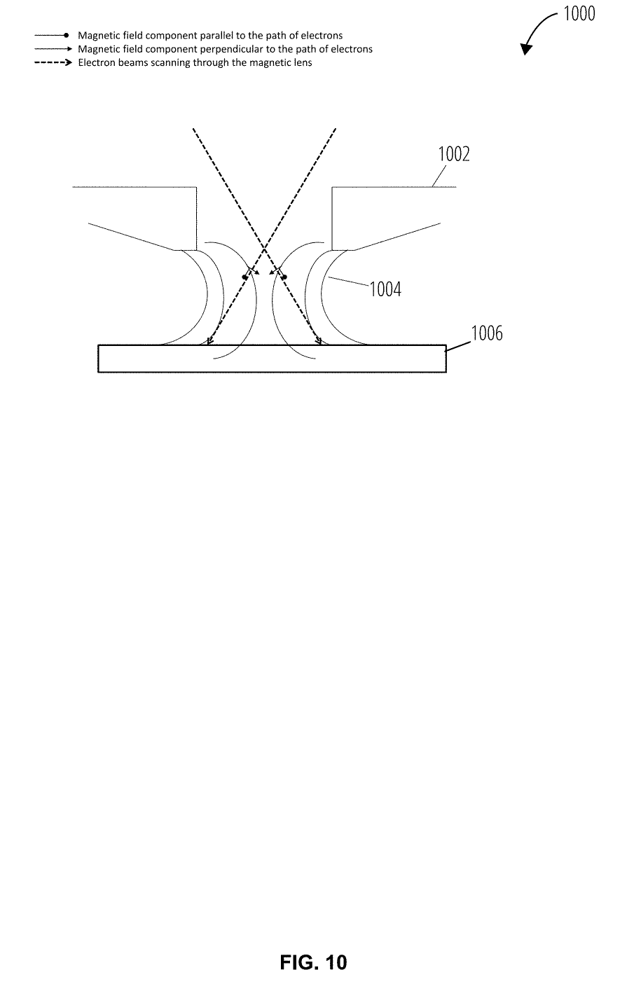

FIG. 10 illustrates that magnetic lens fields (magnetic field lines 1004) will have components perpendicular to the electron beam path, causing dispersion in large field of view. When an electron beam scans through a magnetic lens (magnetic polepiece 1002) in a large field of view to the sample 1006, it goes through the magnetic field with strong components, perpendicular to the electron trajectories. This creates a spectrometer effect, which disperses electrons according to their energies.

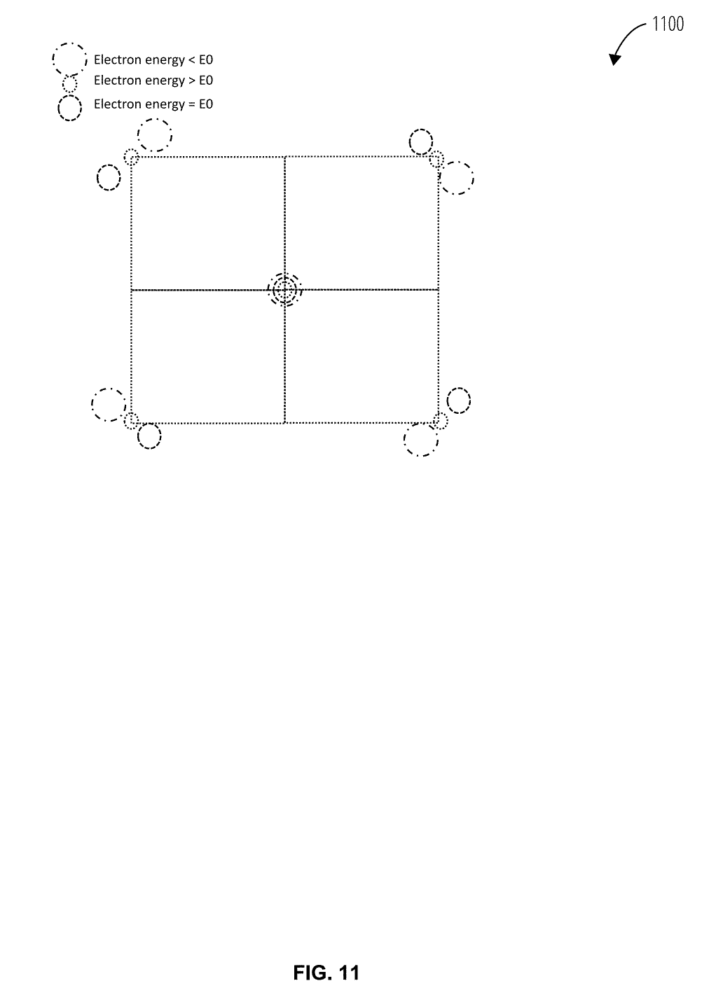

FIG. 11 illustrates that there is focused position shifts of primary electrons 1100 with different energies at a distance away from the electron optical axis, while there is no such primary electron energy related shifts on the electron optical axis.

The focused beam profile on the sample in the large field of view will have dispersion effect and different focus shifting according electron energies.

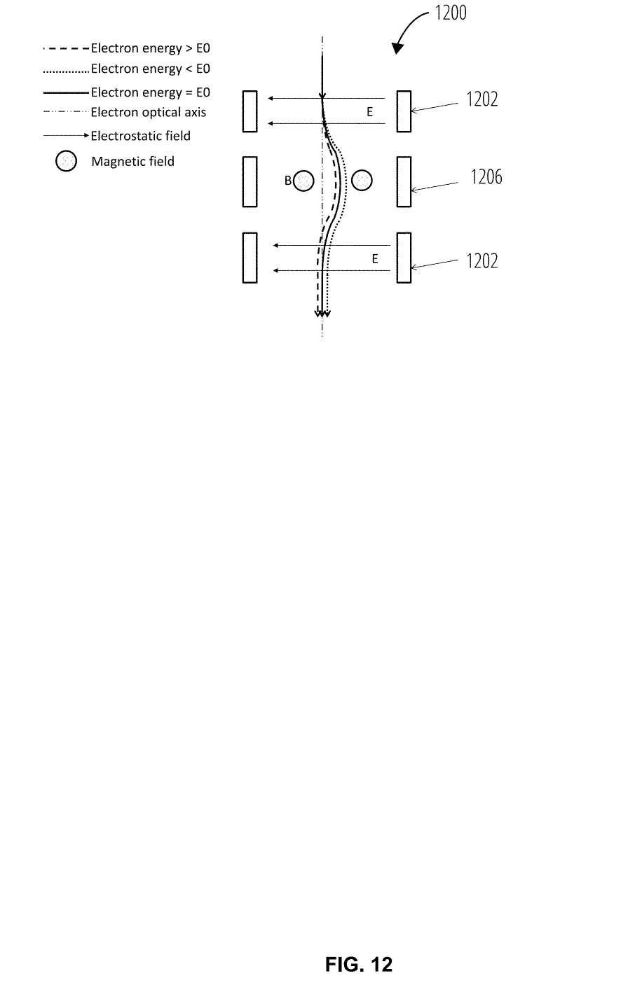

FIG. 12 illustrates a dispersion corrector 1200 of two 2D electrostatic deflectors 1202 and one 2D magnetic deflector 1206 to correct electron beam dispersion on the sample plane, which may be caused by Wien Filters or an objective lens field in large field of view scanning mode. The electron beam is finally deflected back to the original direction and position of primary electron optical axis.

A setup with one magnetic deflector 1206 in between two electrostatic deflectors 1202 can introduce a dispersion effect, while bring back the electron beam trajectories back to optical axis. This dispersion effect is calculated so that it will cancel the dispersion of electron beam scanning for a certain field of view.

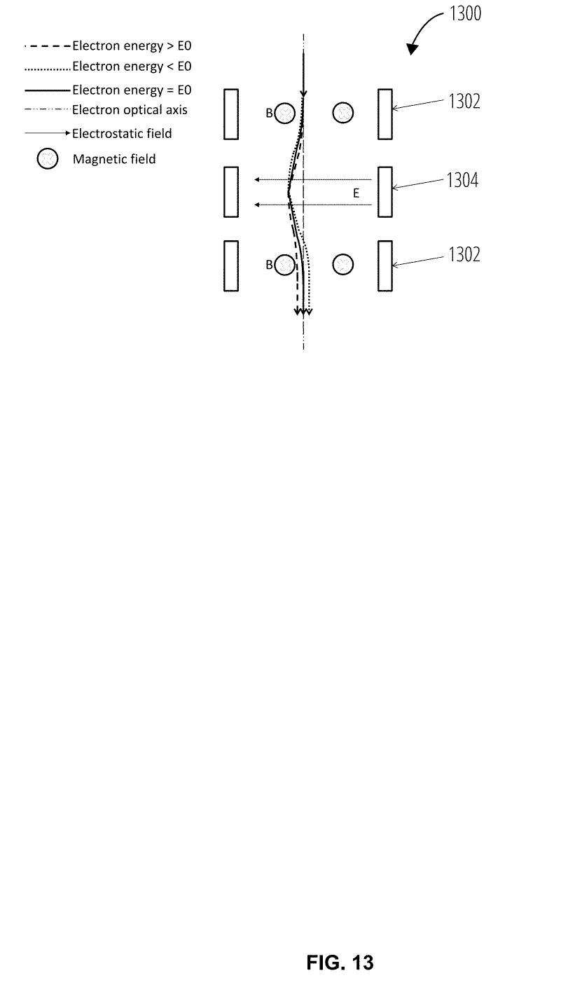

FIG. 13 illustrates another dispersion corrector 1300, which uses two 2D magnetic deflectors 1302 and one 2D electrostatic deflector 1304 to correct electron beam dispersion on the sample plane, which may be caused by Wien Filters or an objective lens field in large field of view scanning mode. In this setup, there is one 2D electrostatic deflector 1304 in between two 2D magnetic deflectors 1302.

A setup with one electrostatic deflector 1304 in between two magnetic deflectors 1302 can also introduce a dispersion effect, while bring back the electron beam trajectories back to optical axis. This dispersion effect is calculated so that it will cancel the dispersion of electron beam scanning for a certain field of view.

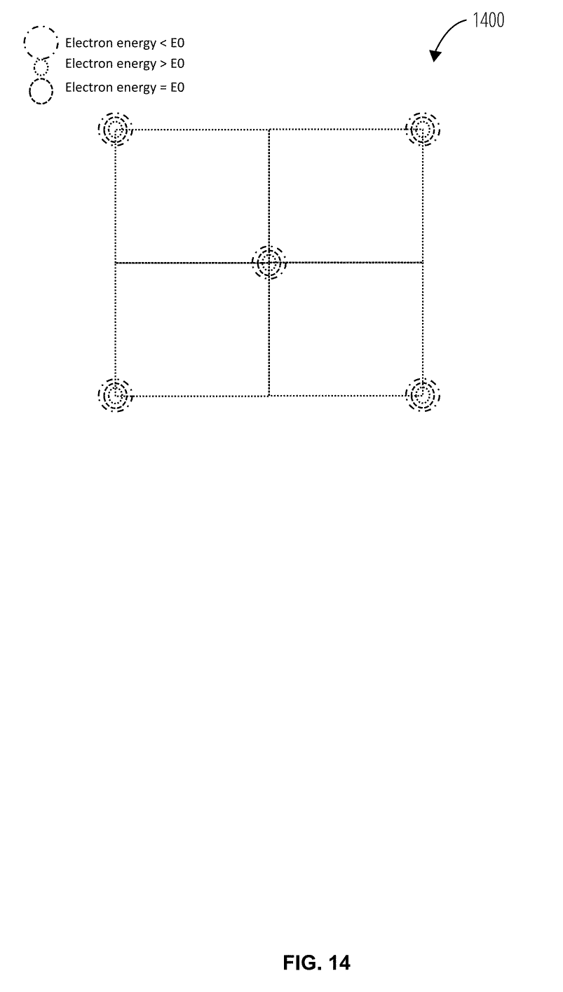

FIG. 14 illustrates that when the dispersion correction using configurations of deflectors in FIG. 12 and FIG. 13 are synchronized with scanning signals, the dispersion errors can be fully corrected (corrected dispersion effects 1400) across the whole scanned field of view.

When the dispersion cancellation by a series of magnetic and electrostatic deflectors are synchronized with electron beam scanning, dispersion effect from the electron beam focusing lens can be corrected across the whole field of view. This effect is similar when electrostatic lens are used for focusing.

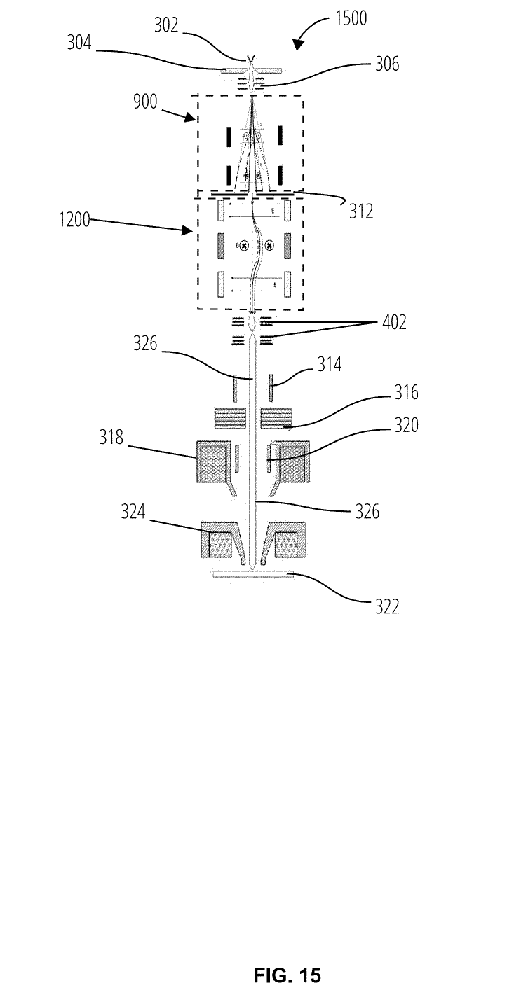

FIG. 15 illustrates an electron beam column 1500 including the double Wein filter monochromator (double Wein filter 900, dispersion corrector 1200) and a dispersion error corrector using two 2D electrostatic deflectors 1202 and one 2D magnetic deflector 1206.

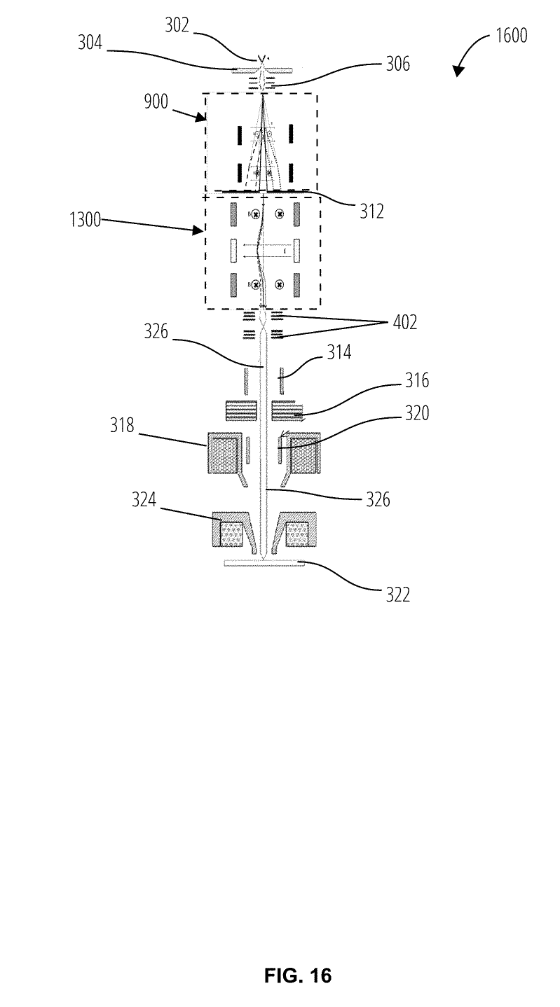

FIG. 16 illustrates a electron beam column 1600 including a double Wein filter (double Wein filter 900, dispersion corrector 1300) monochromator and a dispersion error corrector using two 2D magnetic deflectors 1302 and one 2D electrostatic deflector 1304.

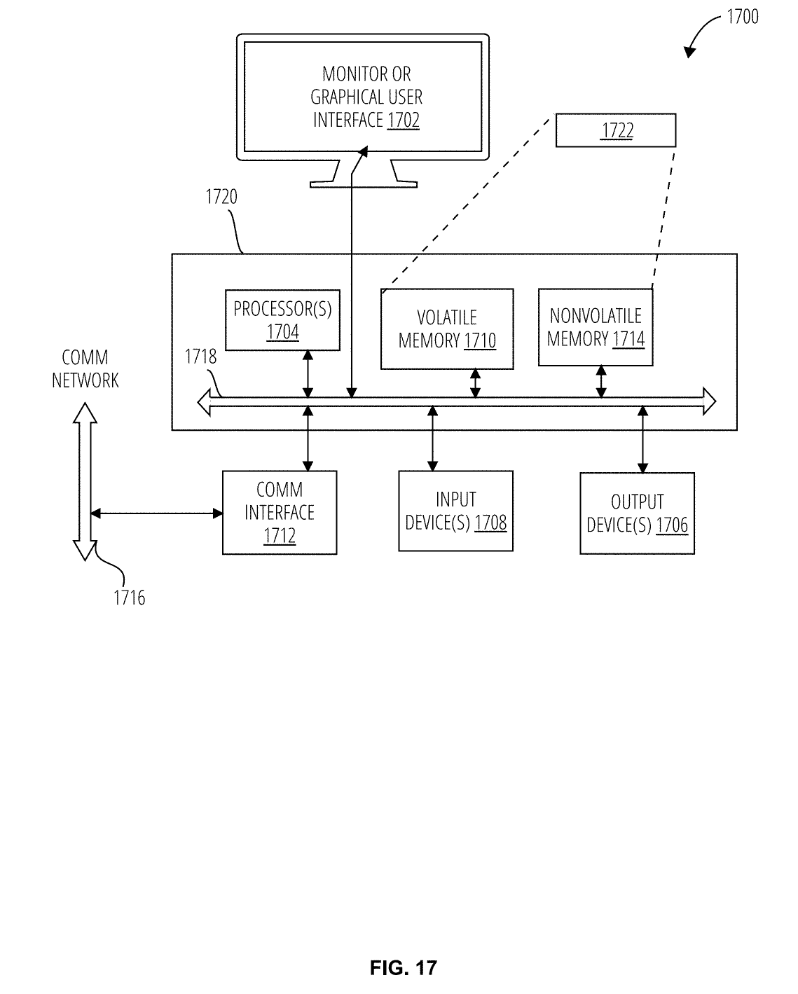

FIG. 17 is an example block diagram of a computing device 1700 that may incorporate embodiments of the present invention. FIG. 17 is merely illustrative of a machine system to carry out aspects of the technical processes described herein (e.g., selecting and operating one or more beam columns of an array 100), and does not limit the scope of the claims. One of ordinary skill in the art would recognize other variations, modifications, and alternatives. In one embodiment, the computing device 1700 typically includes a monitor or graphical user interface 1702, a data processing system 1720, a communication network interface 1712, input device(s) 1708, output device(s) 1706, and the like.

As depicted in FIG. 17, the data processing system 1720 may include one or more processor(s) 1704 that communicate with a number of peripheral devices via a bus subsystem 1718. These peripheral devices may include input device(s) 1708, output device(s) 1706, communication network interface 1712, and a storage subsystem, such as a volatile memory 1710 and a nonvolatile memory 1714.

The volatile memory 1710 and/or the nonvolatile memory 1714 may store computer-executable instructions and thus forming logic 1722 that when applied to and executed by the processor(s) 1704 implement embodiments of the processes disclosed herein.

The input device(s) 1708 include devices and mechanisms for inputting information to the data processing system 1720. These may include a keyboard, a keypad, a touch screen incorporated into the monitor or graphical user interface 1702, audio input devices such as voice recognition systems, microphones, and other types of input devices. In various embodiments, the input device(s) 1708 may be embodied as a computer mouse, a trackball, a track pad, a joystick, wireless remote, drawing tablet, voice command system, eye tracking system, and the like. The input device(s) 1708 typically allow a user to select objects, icons, control areas, text and the like that appear on the monitor or graphical user interface 1702 via a command such as a click of a button or the like.

The output device(s) 1706 include devices and mechanisms for outputting information from the data processing system 1720. These may include speakers, printers, infrared LEDs, and so on as well understood in the art.

The communication network interface 1712 provides an interface to communication networks (e.g., communication network 1716) and devices external to the data processing system 1720. The communication network interface 1712 may serve as an interface for receiving data from and transmitting data to other systems. Embodiments of the communication network interface 1712 may include an Ethernet interface, a modem (telephone, satellite, cable, ISDN), (asynchronous) digital subscriber line (DSL), FireWire, USB, a wireless communication interface such as BlueTooth or WiFi, a near field communication wireless interface, a cellular interface, and the like.

The communication network interface 1712 may be coupled to the communication network 1716 via an antenna, a cable, or the like. In some embodiments, the communication network interface 1712 may be physically integrated on a circuit board of the data processing system 1720, or in some cases may be implemented in software or firmware, such as “soft modems”, or the like.

The computing device 1700 may include logic that enables communications over a network using protocols such as HTTP, TCP/IP, RTP/RTSP, IPX, UDP and the like.

The volatile memory 1710 and the nonvolatile memory 1714 are examples of tangible media configured to store computer readable data and instructions to implement various embodiments of the processes described herein. Other types of tangible media include removable memory (e.g., pluggable USB memory devices, mobile device SIM cards), optical storage media such as CD-ROMS, DVDs, semiconductor memories such as flash memories, non-transitory read-only-memories (ROMS), battery-backed volatile memories, networked storage devices, and the like. The volatile memory 1710 and the nonvolatile memory 1714 may be configured to store the basic programming and data constructs that provide the functionality of the disclosed processes and other embodiments thereof that fall within the scope of the present invention.

Logic 1722 that implements embodiments of the present invention may be stored in the volatile memory 1710 and/or the nonvolatile memory 1714. Said software may be read from the volatile memory 1710 and/or nonvolatile memory 1714 and executed by the processor(s) 1704. The volatile memory 1710 and the nonvolatile memory 1714 may also provide a repository for storing data used by the software.

The volatile memory 1710 and the nonvolatile memory 1714 may include a number of memories including a main random access memory (RAM) for storage of instructions and data during program execution and a read only memory (ROM) in which read-only non-transitory instructions are stored. The volatile memory 1710 and the nonvolatile memory 1714 may include a file storage subsystem providing persistent (non-volatile) storage for program and data files. The volatile memory 1710 and the nonvolatile memory 1714 may include removable storage systems, such as removable flash memory.

The bus subsystem 1718 provides a mechanism for enabling the various components and subsystems of data processing system 1720 communicate with each other as intended. Although the communication network interface 1712 is depicted schematically as a single bus, some embodiments of the bus subsystem 1718 may utilize multiple distinct busses.

It will be readily apparent to one of ordinary skill in the art that the computing device 1700 may be a mobile device such as a smartphone, a desktop computer, a laptop computer, a rack-mounted computer system, a computer server, or a tablet computer device. As commonly known in the art, the computing device 1700 may be implemented as a collection of multiple networked computing devices. Further, the computing device 1700 will typically include operating system logic (not illustrated) the types and nature of which are well known in the art.

“Circuitry” in this context refers to electrical circuitry having at least one discrete electrical circuit, electrical circuitry having at least one integrated circuit, electrical circuitry having at least one application specific integrated circuit, circuitry forming a general purpose computing device configured by a computer program (e.g., a general purpose computer configured by a computer program which at least partially carries out processes or devices described herein, or a microprocessor configured by a computer program which at least partially carries out processes or devices described herein), circuitry forming a memory device (e.g., forms of random access memory), or circuitry forming a communications device (e.g., a modem, communications switch, or optical-electrical equipment).

“Firmware” in this context refers to software logic embodied as processor-executable instructions stored in read-only memories or media.

“Hardware” in this context refers to logic embodied as analog or digital circuitry.

“Logic” in this context refers to machine memory circuits, non transitory machine readable media, and/or circuitry which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter).

“Programmable device” in this context refers to an integrated circuit designed to be configured and/or reconfigured after manufacturing. The term “programmable processor” is another name for a programmable device herein. Programmable devices may include programmable processors, such as field programmable gate arrays (FPGAs), configurable hardware logic (CHL), and/or any other type programmable devices. Configuration of the programmable device is generally specified using a computer code or data such as a hardware description language (HDL), such as for example Verilog, VHDL, or the like. A programmable device may include an array of programmable logic blocks and a hierarchy of reconfigurable interconnects that allow the programmable logic blocks to be coupled to each other according to the descriptions in the HDL code. Each of the programmable logic blocks may be configured to perform complex combinational functions, or merely simple logic gates, such as AND, and XOR logic blocks. In most FPGAs, logic blocks also include memory elements, which may be simple latches, flip-flops, hereinafter also referred to as “flops,” or more complex blocks of memory. Depending on the length of the interconnections between different logic blocks, signals may arrive at input terminals of the logic blocks at different times.

“Software” in this context refers to logic implemented as processor-executable instructions in a machine memory (e.g. read/write volatile or nonvolatile memory or media).

Herein, references to “one embodiment” or “an embodiment” do not necessarily refer to the same embodiment, although they may. Unless the context clearly requires otherwise, throughout the description and the claims, the words “comprise,” “comprising,” and the like are to be construed in an inclusive sense as opposed to an exclusive or exhaustive sense; that is to say, in the sense of “including, but not limited to.” Words using the singular or plural number also include the plural or singular number respectively, unless expressly limited to a single one or multiple ones. Additionally, the words “herein,” “above,” “below” and words of similar import, when used in this application, refer to this application as a whole and not to any particular portions of this application. When the claims use the word “or” in reference to a list of two or more items, that word covers all of the following interpretations of the word: any of the items in the list, all of the items in the list and any combination of the items in the list, unless expressly limited to one or the other. Any terms not expressly defined herein have their conventional meaning as commonly understood by those having skill in the relevant art(s).

Various logic functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on.

Those skilled in the art will recognize that it is common within the art to describe devices or processes in the fashion set forth herein, and thereafter use standard engineering practices to integrate such described devices or processes into larger systems. At least a portion of the devices or processes described herein can be integrated into a network processing system via a reasonable amount of experimentation. Various embodiments are described herein and presented by way of example and not limitation.

Those having skill in the art will appreciate that there are various logic implementations by which processes and/or systems described herein can be effected (e.g., hardware, software, or firmware), and that the preferred vehicle will vary with the context in which the processes are deployed. If an implementer determines that speed and accuracy are paramount, the implementer may opt for a hardware or firmware implementation; alternatively, if flexibility is paramount, the implementer may opt for a solely software implementation; or, yet again alternatively, the implementer may opt for some combination of hardware, software, or firmware. Hence, there are numerous possible implementations by which the processes described herein may be effected, none of which is inherently superior to the other in that any vehicle to be utilized is a choice dependent upon the context in which the implementation will be deployed and the specific concerns (e.g., speed, flexibility, or predictability) of the implementer, any of which may vary. Those skilled in the art will recognize that optical aspects of implementations may involve optically-oriented hardware, software, and or firmware.

Those skilled in the art will appreciate that logic may be distributed throughout one or more devices, and/or may be comprised of combinations memory, media, processing circuits and controllers, other circuits, and so on. Therefore, in the interest of clarity and correctness logic may not always be distinctly illustrated in drawings of devices and systems, although it is inherently present therein. The techniques and procedures described herein may be implemented via logic distributed in one or more computing devices. The particular distribution and choice of logic will vary according to implementation.

The foregoing detailed description has set forth various embodiments of the devices or processes via the use of block diagrams, flowcharts, or examples. Insofar as such block diagrams, flowcharts, or examples contain one or more functions or operations, it will be understood as notorious by those within the art that each function or operation within such block diagrams, flowcharts, or examples can be implemented, individually or collectively, by a wide range of hardware, software, firmware, or virtually any combination thereof. Portions of the subject matter described herein may be implemented via Application Specific Integrated Circuits (ASICs), Field Programmable Gate Arrays (FPGAs), digital signal processors (DSPs), or other integrated formats. However, those skilled in the art will recognize that some aspects of the embodiments disclosed herein, in whole or in part, can be equivalently implemented in standard integrated circuits, as one or more computer programs running on one or more processing devices (e.g., as one or more programs running on one or more computer systems), as one or more programs running on one or more processors (e.g., as one or more programs running on one or more microprocessors), as firmware, or as virtually any combination thereof, and that designing the circuitry or writing the code for the software or firmware would be well within the skill of one of skill in the art in light of this disclosure. In addition, those skilled in the art will appreciate that the mechanisms of the subject matter described herein are capable of being distributed as a program product in a variety of forms, and that an illustrative embodiment of the subject matter described herein applies equally regardless of the particular type of signal bearing media used to actually carry out the distribution. Examples of a signal bearing media include, but are not limited to, the following: recordable type media such as floppy disks, hard disk drives, CD ROMs, digital tape, flash drives, SD cards, solid state fixed or removable storage, and computer memory.

In a general sense, those skilled in the art will recognize that the various aspects described herein which can be implemented, individually or collectively, by a wide range of hardware, software, firmware, or any combination thereof can be viewed as being composed of various types of circuitry.

What is claimed is:

1. An apparatus comprising:
at least one electron beam column, comprising an electron emitter source, a gun lens focusing electrons from the electron emitter source into an electron beam, and a final beam forming aperture;
each electron beam column comprising one or more of:
a double Wein filter disposed along a trajectory of the electron beam between the gun lens and the final beam forming aperture; and
a dispersion corrector disposed along a trajectory of the electron beam after the final beam forming aperture.

2. The apparatus of claim 1, the dispersion corrector configured to generate 2D dispersion corrections synchronized with a scanning signal for the electron beam column.

3. The apparatus of claim 1, the double Wein filter configured to generate a static energy filtering signal, the static energy filtering signal not synchronized with a scanning signal for the electron beam column.

4. The apparatus of claim 1, the dispersion corrector comprising two 2D electrostatic deflectors and one 2D magnetic deflector.

5. The apparatus of claim 4, the one 2D magnetic deflector being disposed between the two 2D electrostatic deflectors along the trajectory of the electron beam.

6. The apparatus of claim 1, the dispersion corrector comprising two 2D magnetic deflectors and one 2D electrostatic deflector.

7. The apparatus of claim 6, the one 2D electrostatic deflector being disposed between the two 2D magnetic deflectors along the trajectory of the electron beam.

8. The apparatus of claim 1, each at least one beam column further comprising:
a coil-driven adjustment lens; and
a permanent magnet objective lens.

9. The apparatus of claim 1, each at least one beam column further comprising:
a beam blanker operable to deflect the electron beam from passing through the final beam forming aperture.

10. The apparatus of claim 1, comprising a plurality of electron beam columns in a functional group, each of the plurality of electron beam columns independently operable from one another.

11. The apparatus of claim 10, comprising four electron beam columns in the functional group, each of the four electron beam columns independently operable from one another.

12. The apparatus of claim 1, the at least one electron beam column further comprising:
a set of condenser lenses;
both of:
the double Wein filter; and
the dispersion corrector.

13. An electron beam column, comprising:
an electron emitter source;
a gun lens focusing electrons from the electron emitter source into an electron beam;
a set of condenser lenses;
a final beam forming aperture;
a double Wein filter disposed along a trajectory of the electron beam between the gun lens and the final beam forming aperture; and
a dispersion corrector disposed along a trajectory of the electron beam after the final beam forming aperture.

14. The electron beam column of claim 13, the dispersion corrector configured to generate 2D dispersion corrections synchronized with a scanning signal for the electron beam column.

15. The electron beam column of claim 13, the double Wein filter configured to generate a static energy filtering signal, the static energy filtering signal not synchronized with a scanning signal for the electron beam column.

16. The electron beam column of claim 13, the dispersion corrector comprising two 2D electrostatic deflectors and one 2D magnetic deflector.

17. The electron beam column of claim 16, the one 2D magnetic deflector disposed between the two 2D electrostatic deflectors along the trajectory of the electron beam.

18. The electron beam column of claim 13, the dispersion corrector comprising two 2D magnetic deflectors and one 2D electrostatic deflector.

19. The electron beam column of claim 18, the one 2D electrostatic deflector disposed between the two 2D magnetic deflectors along the trajectory of the electron beam.

20. The electron beam column of claim 13, each at least one beam column further comprising:
a coil-driven adjustment lens; and
a permanent magnet objective lens.

21. The electron beam column of claim 13, each at least one beam column further comprising:
an electron beam aperture preceding the set of condenser lenses along the trajectory of the electron beam; and
a beam blanker operable to deflect the electron beam from passing through the final beam forming aperture.

22. The electron beam column of claim 13, comprising a plurality of electron beam columns in a functional group, each of the plurality of electron beam columns independently operable from one another.

23. The electron beam column of claim 22, comprising four electron beam columns in the functional group, each of the four electron beam columns independently operable from one another.
